(19) United States
(12) Patent Application Publication
(10) Pub. No.: US 2020/0066858 A1
(43) Pub. Date: Feb. 27, 2020

(54) HIGH PERFORMANCE THIN FILM TRANSISTOR WITH NEGATIVE INDEX MATERIAL

(71) Applicant: QUALCOMM Incorporated, San Diego, CA (US)

(72) Inventors: Junjing BAO, San Diego, CA (US); Peijie FENG, San Diego, CA (US); Ye LU, San Diego, CA (US); Bin YANG, San Diego, CA (US)

(21) Appl. No.: 16/112,484

(22) Filed: Aug. 24, 2018

(51) Int. Cl. H01L 29/423; H01L 29/786; H01L 29/51; H01L 29/66

(52) U.S. Cl. CPC H01L 29/42356; H01L 29/78666; H01L 29/78669; H01L 29/7869; H01L 29/66765; H01L 29/513; H01L 29/66969; H01L 29/66757; H01L 29/517

(57) ABSTRACT

A thin film transistor may include an insulating substrate and a layer of semiconductor material disposed over the insulating substrate. The thin film transistor may further include a gate electrode, a source electrode and a drain electrode disposed over the insulating substrate. The thin film transistor may further include a layer of first dielectric material disposed in between the gate electrode and the source and drain electrodes, and a layer of second dielectric material in contact with the layer of first dielectric material. The second dielectric material has a negative index.

### BACKGROUND

### Field

Aspects of the present disclosure relate to thin film transistors, and more particularly to a thin film transistor having a negative index material.

### Background

Thin film transistors (TFTs) are a special kind of field-effect transistor made by depositing thin films of an active semiconductor layer as well as the dielectric layer and metal contacts over a supporting but non-conducting substrate. TFTs are commonly used in flat panel displays, computers, smart phones, video systems, and RFID chips.

When producing TFTs, large area uniformity, low processing temperatures and good electrical performance are desired. Electrical performance, however, may be limited because TFTs are typically built on glass, which has poor electron mobility. It is desired to improve the electrical performance of TFTs.

### SUMMARY

A thin film transistor may include an insulating substrate and a layer of semiconductor material disposed over the insulating substrate. The thin film transistor may further include a gate electrode, a source electrode and a drain electrode disposed over the insulating substrate. The thin film transistor may further include a layer of first dielectric material disposed in between the gate electrode and the source and a drain electrodes, and a layer of second dielectric material in contact with the layer of first dielectric material. The second dielectric material has a negative index to boost the electrical performance of the thin film transistor.

A method of fabricating a thin film transistor includes preparing an insulating substrate and forming a gate electrode on the insulating substrate. The method further includes depositing a layer of first dielectric material and a layer of second dielectric material over the gate electrode and the insulating substrate. The second dielectric material has a negative index. The method further includes depositing a layer of semiconductor material over the layer of first dielectric material and the layer of second dielectric material. The method further includes forming a source electrode and a drain electrode over the layer of first dielectric material and the layer of second dielectric material.

This has outlined, rather broadly, the features and technical advantages of the present disclosure that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of an aspect of the present disclosure, reference is now made to the following description taken in conjunction with the accompanying drawings.

FIGS. 1A-1D illustrate cross-sectional views of TFT structures, according to aspects of the present disclosure.

FIG. 2 illustrates a method of a fabricating a TFT structure in accordance with an aspect of the present disclosure.

FIG. 3 is a block diagram showing an exemplary wireless communication system in which an aspect of the disclosure may be advantageously employed.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR”, and the use of the term “or” is intended to represent an “exclusive OR”. As described herein, the term “exemplary” used throughout this description means “serving as an example, instance, or illustration,” and should not necessarily be construed as preferred or advantageous over other exemplary configurations. As described herein, the term “proximate” used throughout this description means “adjacent, very near, next to, or close to.” As described herein, the term “on” used throughout this description means “directly on” in some configurations, and “indirectly on” in other configurations.

According to aspects of the present disclosure, a thin film transistor (TFT) is described in which a second dielectric material, comprised of a negative index material, is in contact with a first dielectric material. The first dielectric material is a conventional positive index material, such as a high-k dielectric. The resulting combination of the two dielectric materials increases the effective gate capacitance of the TFT. The increased gate capacitance of the TFT positively impacts the drain to source current of the TFT, thereby improving its electrical performance.

According to an aspect of the present disclosure, a negative index material is selected such that the absolute value of its capacitance is slightly larger than that of the positive index material. For example, the negative index material may have a capacitance C2 that has an absolute value that is 1.1 times that of the positive index material, C1. A resulting capacitor that utilizes the negative index material in series with the positive index material would have a capacitance increase of 11 times that of a similarly sized capacitor containing only the positive index material. The negative index material may include lead zirconate titanate (PZT), like PbZrTiO₃, or HfZrO₂.

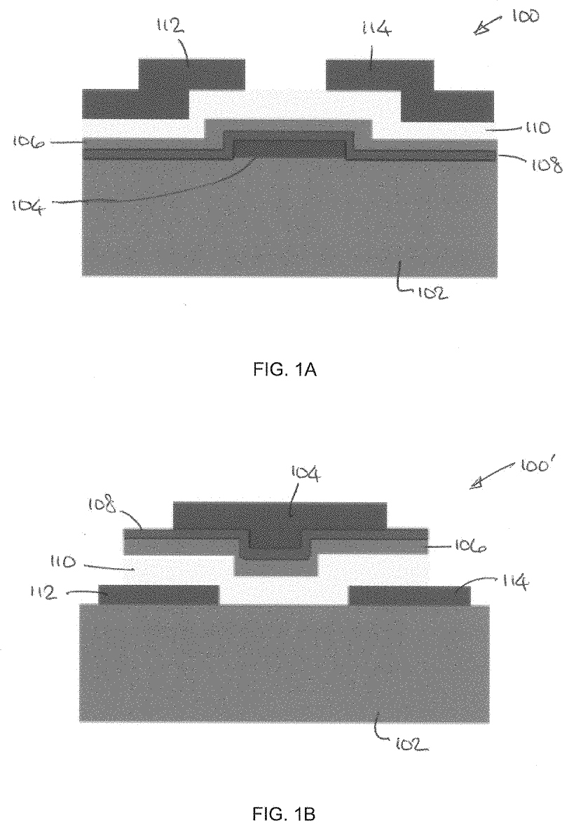

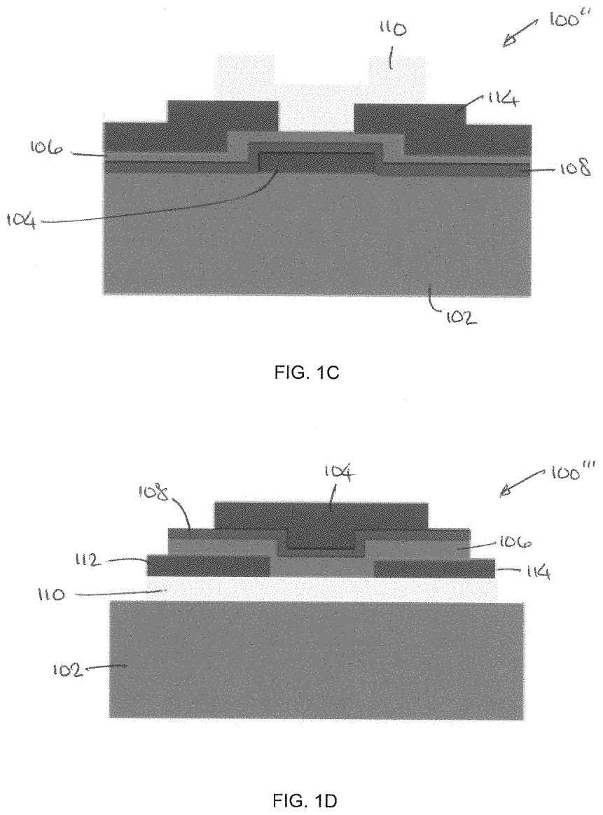

FIG. 1A illustrates a cross-sectional view of a TFT structure 100, according to an aspect of the present disclosure. The TFT structure 100 shown in FIG. 1A has a staggered bottom-gate configuration. The TFT structure 100 includes an insulating substrate 102. The insulating substrate is typically a glass substrate. A gate electrode 104 may be formed on the insulating substrate 102. The gate electrode may be composed of a transparent material, such as indium tin oxide (ITO).

The TFT structure 100 includes two layers of dielectric material disposed over the gate electrode 104 and the insulating substrate 102: a first dielectric material 106; and a second dielectric material 108. The first dielectric material 106 may be a conventional, positive index, dielectric material, such a silicon dioxide (SiO₂) or hafnium dioxide (HfO₂). The first dielectric material 106 may also be a high-k dielectric material, like hafnium silicate, zirconium silicate, hafnium dioxide and zirconium dioxide.

The second dielectric material 108 may be a negative index material that exhibits a negative differential capacitance, such that when a voltage pulse is applied, the voltage across the material will decrease with time. Examples of such a negative index material may include lead zirconate titanate (PZT) (e.g., PbZrTiO₃) and HfZrO₂.

As illustrated in FIG. 1A, the layer of second dielectric material 108 is disposed directly on the gate electrode 104 and the insulating substrate 102, and the layer of first dielectric material 106 is disposed on the layer of second dielectric material 108. Alternatively, the layer of first dielectric material 106 may be disposed directly on the gate electrode 104 and the insulating substrate 102, with the layer of second dielectric material 108 disposed on the layer of first dielectric material 106.

The TFT structure 100 further includes a layer of semiconductor material 110 disposed over the layer of first dielectric material 106 and the layer of second dielectric material 108. The semiconductor material 110 may be composed of hydrogenated amorphous silicon (a-Si:H) or microcrystalline silicon. Alternatively, the semiconductor material 110 may be composed of indium gallium zinc oxide (IGZO).

A source electrode 112 and a drain electrode 114 are formed on the layer of semiconductor material 110. The source and drain electrodes 112 and 114 are formed of any suitable conductive material, such as copper or ITO.

A key electrical performance indicator of the TFT structure 100 is its drain-to-source current I_{DS}. In a linear mode, the drain-to-source current I_{DS} is defined by the equation:

$${I}_{DS} = {C}_{i} \text{?} \frac{W}{L} [ ( {V}_{GS} - {V}_{T} ) {V}_{DS} - \frac{1}{2} {V}_{DS}^{2} ] , \\ \text{?} \text{indicates text missing or illegible when filed}$$

while in a saturation mode, the drain-to-source current I_{DS} is defined by the equation:

$${I}_{DS} = \frac{1}{2} {C}_{i} \text{?} \frac{W}{L} {( {V}_{GS} - {V}_{T} )}^{2} , \\ \text{?} \text{indicates text missing or illegible when filed}$$

where Cᵢ is the gate capacitance, μ is the electron mobility, W is the width of the channel, L is the length of the channel, V_{GS} is the gate-source voltage, V_{T} is the threshold voltage, and V_{DS} is the drain-source voltage. From the equations above, it is clear that the drain-to-source current I_{DS} correlates with the gate capacitance Cᵢ. An increase in the gate capacitance Ci of the TFT structure 100 will increase the drain-to-source current I_{DS}, which improves the electrical performance of the TFT structure 100.

The gate capacitance Cᵢ of the TFT structure 100 is enhanced by the addition of the layer of second dielectric material 108. The negative index dielectric material 108 works in series with the positive index first dielectric material 106 to increase the effective gate capacitance of the TFT structure 100. The gate capacitance Cᵢ of the TFT structure 100 is defined by the following equation:

$$Ci = \frac{\vert C 2 \vert}{\vert C 2 \vert - C 1} \cdot C 1 ,$$

where C1 is the capacitance of the first dielectric material 106, and |C2| is the absolute value of the capacitance of the second dielectric material 108, since the capacitance C2 may be a negative value.

To maximize the increased capacitance of the TFT structure 100, the second dielectric material 108, which is comprised of the negative index material, may be selected such that the absolute value of the second capacitance |C2| is larger than, but close to, the first capacitance C1 of the first dielectric material 106. For example, if |C2|=1.1×C1, then Cᵢ=11×C1, an increase of eleven times the first capacitance C1 of the first dielectric material 106.

FIGS. 1B-1D illustrate cross-sectional view of alternate TFT structure configurations, according to aspects of the present disclosure. Common elements between FIG. 1A and FIGS. 1B-1D are shown with common reference numbers and thus will not be re-described.

FIG. 1B shows a TFT structure 100′ that has a staggered top-gate configuration. The configuration is staggered, because the source and drain electrodes 112 and 114, respectively, of the TFT structure 100′ are on opposite sides of the layer of semiconductor material 110 than the gate electrode 104. The configuration is “top-gate,” because the gate electrode 104 is located at the top of the TFT structure 100′.

As shown in FIG. 1B, the source electrode 112 and the drain electrode 114 are disposed on the insulating substrate 102, and the layer of semiconductor material 110 is disposed on the insulating substrate 102 and the source and drain electrodes 112 and 114, respectively. In between the layer of semiconductor material 110 and the top gate 104 are the layer of first dielectric material 106 and the layer of second dielectric material 108. As shown in FIG. 1B, the layer of second dielectric material 108 is disposed on the layer of first dielectric material 106. In an alternate configuration the placement of the first and second dielectric materials 106 and 108, respectively, may be switched, with the layer of second dielectric material 108 disposed directly on the layer of semiconductor material 110.

FIG. 1C shows a TFT structure 100″ that has a coplanar bottom-gate structure. The configuration is coplanar, because the source electrode 112, the drain electrode 114, and the gate electrode 104 are all on the same side of the semiconductor material 110. The configuration is bottom-gate, because the gate electrode 104 is at the bottom of the TFT structure 100″.

As shown in FIG. 1C, the gate electrode 104 is formed on the insulating substrate 102. The layer of first dielectric material 106 and the layer of second dielectric material 108 are both disposed over the insulating substrate 102 and the gate electrode 104. As shown in FIG. 1C the layer of first dielectric material 106 is on the layer of second dielectric material 108, but as discussed previously, their placement may be switched. The source electrode 112 and the drain electrode 114 are formed over the layers of first dielectric material 106 and second dielectric material 108. The layer of semiconductor material 110 is disposed on the source and drain electrodes, 112 and 114, respectively.

FIG. 1D shows a TFT structure 100′″ that has a coplanar top-gate structure. The layer of semiconductor material 110 is disposed on the insulating substrate 102. The source and drain electrodes 112 and 114, respectively, are formed on the semiconductor material 110, and are separated from the top gate electrode 104 by the layers of first dielectric material 106 and second dielectric material 108. As shown in FIG. 1D, the layer of second dielectric material 108 is disposed on the layer of first dielectric material 106, however, their arrangement may also be reversed.

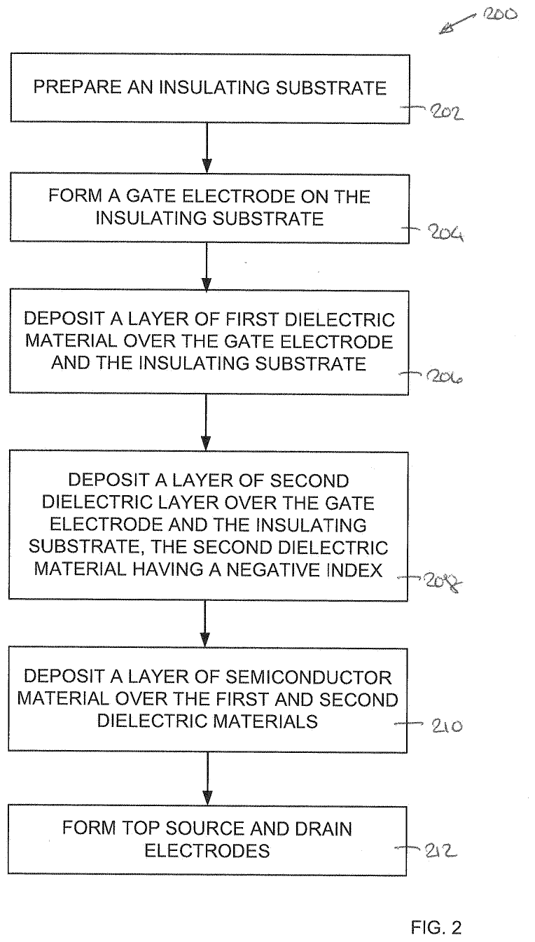

FIG. 2 illustrates a method 200 of making a TFT structure 100 as illustrated in FIG. 1A according to an aspect of the present disclosure. In block 202, an insulating substrate 202 is prepared. The insulating substrate 202 may be composed of glass or any other suitable supportive and insulating material.

In block 204, a gate electrode 104 is formed on the insulating substrate 102. The gate electrode 104. The gate electrode may be composed of a transparent material, such as ITO.

In block 206, a layer of first dielectric material 106 is deposited over the gate electrode 104 and the insulating substrate 102. The first dielectric material may be a positive index material, such as silicon dioxide. The first dielectric material may also be a high-k dielectric material, like hafnium silicate, zirconium silicate, hafnium dioxide and zirconium dioxide.

In block 208, a layer of second dielectric material 108 is deposited over the gate electrode 104 and the insulating substrate 102. The second dielectric material 108 may be deposited at a low processing temperature (e.g., under 300° C.) using plasma enhanced atomic layer deposition (ALD). The second dielectric material 108 is a negative index material, such as lead zirconate titanate or HfZrO₂. The second dielectric material 108 is selected to have a capacitance, the absolute value of which is slightly larger than that of the first dielectric material 106. The resulting combination of the first dielectric material 106 and the second dielectric material 108 increases the effective gate capacitance of the TFT. The increased gate capacitance of the TFT positively impacts the drain to source current of the TFT and improves its overall electrical performance.

As discussed above the deposition of the layers of first dielectric material 106 and second dielectric material 108 may be switched, such that the layer of second dielectric material 108 is deposited first. For example, as illustrated in FIG. 1A, the layer of second dielectric material 108 is deposited directly on the gate electrode 104 and the insulating substrate 102. The layer of first dielectric material 106 is then deposited on the layer of second dielectric material 108.

In block 210, a layer of semiconductor material is deposited over the first and second dielectric materials. The semiconductor material may be a hydrogenated amorphous silicon, microcrystalline silicon, or IGZO. As shown in FIG. 1A, the layer of semiconductor material 110 is provided on the layer of first dielectric material 106. However, as noted above, if the layers of first and second dielectric materials 106 and 108, respectively, are reversed, then the semiconductor material 110 may be provided directly on the layer of second dielectric material 108.

In block 212, the source and drain electrodes are formed. As shown in FIG. 1A, the source electrode 112 and the drain electrode 114 are formed on the layer of semiconductor material 110. This TFT structure 100 has a staggered bottom-gate configuration. The source and drain electrodes 112 and 114, respectively, are composed of a suitable conductive material, such as copper or ITO.

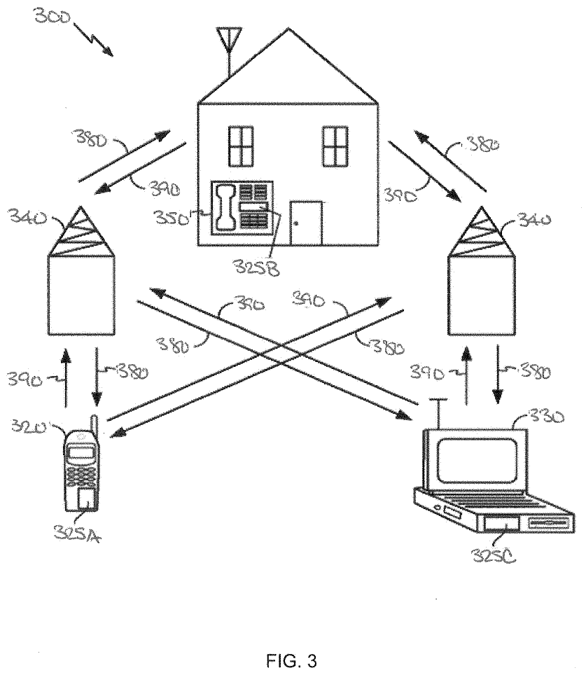

FIG. 3 is a block diagram showing an exemplary wireless communication system 300 in which an aspect of the disclosure may be advantageously employed. For purposes of illustration, FIG. 5 shows three remote units 320, 330, and 350 and two base stations 340. It will be recognized that wireless communication systems may have many more remote units and base stations. Remote units 320, 330, and 350 include IC devices 325A, 325C, and 325B that include the disclosed TFTs. It will be recognized that other devices may also include the disclosed TFTs. FIG. 3 shows forward link signals 380 from the base station 340 to the remote units 320, 330, and 350 and reverse link signals 390 from the remote units 320, 330, and 350 to base stations 340.

In FIG. 3, remote unit 320 is shown as a mobile telephone, remote unit 330 is shown as a portable computer, and remote unit 350 is shown as a fixed location remote unit in a wireless local loop system. For example, the remote units may be a mobile phone, a hand-held personal communication systems (PCS) unit, a portable data unit such as a personal data assistant, a GPS enabled device, a navigation device, a set top box, a music player, a video player, an entertainment unit, a fixed location data unit such as a meter reading equipment, or other devices that store or retrieve data or computer instructions, or combinations thereof. Although FIG. 3 illustrates remote units according to the aspects of the disclosure, the disclosure is not limited to these exemplary illustrated units. Aspects of the disclosure may be suitably employed in many devices, which include the disclosed TFTs.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A thin film transistor comprising:
an insulating substrate;
a layer of semiconductor material disposed over the insulating substrate;
a gate electrode disposed over the insulating substrate;
a source electrode and a drain electrode disposed over the insulating substrate, the drain electrode spaced apart from the source electrode;
a layer of first dielectric material disposed between the gate electrode and at least one of the source and drain electrodes, the first dielectric material having a positive index; and
a layer of second dielectric material in contact with the layer of first dielectric material, the second dielectric material having a negative index.

2. The thin film transistor of claim 1, wherein the thin film transistor has a staggered bottom-gate configuration, wherein the gate electrode is disposed on the insulating substrate, and the source and drain electrodes are disposed on the layer of semiconductor material, and wherein the layer of first dielectric material and the layer of second dielectric material are disposed between the gate electrode and the layer of semiconductor material.

3. The thin film transistor of claim 2, wherein the layer of second dielectric material is disposed on the insulating substrate and the gate electrode, and the layer of first dielectric material is on the layer of second dielectric material.

4. The thin film transistor of claim 1, wherein the thin film transistor has a staggered top-gate configuration, wherein the source and drain electrodes are disposed on the insulating substrate, and the layer of semiconductor material is disposed on the source and drain electrodes, and wherein the layer of first dielectric material and the layer of second dielectric material are disposed in between the gate electrode and the layer of semiconductor material.

5. The thin film transistor of claim 4, wherein the layer of first dielectric material is disposed on the layer of semiconductor material, and the layer of second dielectric material is disposed on the layer of first dielectric material.

6. The thin film transistor of claim 1, wherein the thin film transistor has a coplanar bottom-gate configuration, wherein the gate electrode is disposed on the insulating substrate, and the layer of semiconductor material is disposed on the source and drain electrodes, and wherein the layer of first dielectric material and the layer of second dielectric material are disposed in between the gate electrode and the source and drain electrodes.

7. The thin film transistor claim 6, wherein the layer of second dielectric material is disposed on the insulating substrate and the gate electrode, and the source and drain electrodes are disposed on the layer of first dielectric material.

8. The thin film transistor of claim 1, wherein the thin film transistor has a coplanar top-gate configuration, wherein the layer of semiconductor material is disposed on the insulating substrate, the source and drain electrodes are disposed on the layer of semiconductor material, and wherein the layer of first dielectric material and the layer of second dielectric material are disposed in between the gate electrode and the source and drain electrodes.

9. The thin film transistor of claim 8, wherein the layer of first dielectric material is disposed on the source and drain electrodes and the layer of semiconductor material, and the gate electrode is disposed on the layer of second dielectric material.

10. The thin film transistor of claim 1, wherein the first dielectric material is selected from the group consisting of SiO₂ and HfO₂.

11. The thin film transistor of claim 1, wherein the second dielectric material is selected from the group consisting of HfZrO₂ and PbZrTiO₃.

12. The thin film transistor of claim 1, wherein the semiconductor material is selected from the group consisting of hydrogenated amorphous silicon or indium gallium zinc oxide.

13. The thin film transistor of claim 1, integrated into a mobile phone, a set top box, a music player, a video player, an entertainment unit, a navigation device, a computer, a hand-held personal communication systems (PCS) unit, a portable data unit, and/or a fixed location data unit.

14. A method of fabricating a thin film transistor, comprising:
preparing an insulating substrate;
forming a gate electrode on the insulating substrate;
depositing a layer of first dielectric material over the gate electrode and the insulating substrate, the first dielectric material having a positive index;
depositing a layer of second dielectric material over the gate electrode and the insulating substrate, the second dielectric material having a negative index;
depositing a layer of semiconductor material over the layer of first dielectric material and the layer of second dielectric material; and
forming a source electrode and a drain electrode over the layer of first dielectric material and the layer of second dielectric material.

15. The method of claim 14, wherein the layer of second dielectric material is deposited on the insulating substrate and the gate electrode, and the layer of first dielectric material is deposited on the layer of second dielectric material.

16. The method of claim 14, wherein the source electrode and the drain electrode are formed on the layer of semiconductor material.

17. The method of claim 14, wherein the layer of semiconductor material is deposited on the source electrode and the drain electrode.

18. The method of claim 14, wherein the layer of first dielectric material and the layer of second dielectric material are deposited using plasma enhanced atomic layer deposition.

19. The method of claim 14, wherein the first dielectric material is selected from the group consisting of SiO₂ and HfO₂.

20. The method of claim 14, wherein the second dielectric material is selected from the group consisting of HfZrO₂ and PbZrTiO₃.

21. The method of claim 14, wherein the semiconductor material is selected from the group consisting of hydrogenated amorphous silicon or indium gallium zinc oxide.
